(19) United States
(12) Patent Application Publication
(10) Pub. No.: US 2006/0158863 A1
(43) Pub. Date: Jul. 20, 2006

(54) Interconnection structure through passive component

(76) Inventor: Chi-Hsing Hsu, Taipei Hsien (TW)

Correspondence Address: J C PATENTS, INC., 4 VENTURE, SUITE 250, IRVINE, CA, 92618, US

(21) Appl. No.: 11/122,656

(22) Filed: May 4, 2005

(30) Foreign Application Priority Data
Jan. 19, 2005 (TW) 94101499

(51) Int. Cl. H05K 7/06; H05K 1/18

(52) U.S. Cl. 361/760; 361/782; 361/783; 361/803; 257/724

(57) ABSTRACT

An interconnection structure through passive component is provided. The interconnection structure through passive component comprises a first substrate, a second substrate, a plurality of conductive blocks, and at least one passive component. Wherein, the second substrate is disposed on the first substrate. Additionally, the conductive blocks and the passive component are disposed between the first substrate and the second substrate. The first substrate is structurally and electrically connected to the second substrate by the conductive blocks and the passive component.

### CROSS-REFERENCE TO RELATED APPLICATION

This application claims the priority benefit of Taiwan application serial no. 94101499, filed on Jan. 19, 2005. All disclosure of the Taiwan application is incorporated herein by reference.

### BACKGROUND OF THE INVENTION

1. Field of the Invention

This invention generally relates to an interconnection structure, and especially to an interconnection structure through passive component.

2. Description of Related Art

Following the rapid development of electronic technology, many new electronic products with more humanity and multi-functional characters also come into the market. It is the trend that design of the electronic products tends to be light, thin, short, small and attractive. With reduction of line pitches, cross talk caused due to switches of high frequency signals becomes more serious. At present, a passive component is commonly used in circuit distribution of electric package for improving signal transmitting quality. In addition, the passive component is usually disposed on a package substrate of an electric package or on a printed circuit board (PCB). The details of the disposition and location of the passive component will be described later.

FIG. 1 is a drawing schematically showing a cross-sectional view of a conventional interconnection structure through passive component. As shown in FIG. 1, the conventional electric package 100 comprises a package substrate 110, a chip 120, a plurality of first passive components 130, a plurality of solder balls 140 and an underfill 150. The chip 120 has a plurality of bumps 122 disposed between the chip 120 and the package substrate 110. The chip 120 is electrically connected to the package substrate 110 through the bumps 122. In other words, the chip 120, consequently through the conductive pads 124, the bumps 122 and the conductive pads 112, is electrically connected to the package substrate 110. Further, the solder balls 140 are disposed on another surface of the package substrate 110, and the underfill 150 is disposed between the package substrate 110 and the chip 120, for covering the bumps 122. Furthermore, the conventional electric package 100 is electrically connected to a printed circuit board 160 by the solder balls 140. Similarly, the printed circuit board 160, consequently through the conductive pads 162, the solder balls 140 and the conductive pads 114, is electrically connected to the conventional electric package 100.

In addition to the above mentioned, some first passive components 130 are disposed on the surface of the package substrate 110 and positioned at the outer circumference of the chip 120. The first passive components 130 are electrically connected to the package substrate 110. Furthermore, some first passive components 130 are disposed on the surface of the package substrate 110 and positioned between the printed circuit board 160 and the package substrate 110. These first passive components 130 are electrically connected to the package substrate 110. In addition, a plurality of second passive components 170 is disposed at the outer circumference of the package substrate 110 on the surface of the printed circuit board 160. These second passive components 170 are electrically connected to the printed circuit board 160.

Note that the first passive components 130, which are disposed on the package substrate 110 and positioned at the outer circumference of the chip 120, will increase the area of the package substrate 110, and as a result, increase the package area of the conventional electric package 100. Further, when the electrodes 130a of the first passive components 130 are connected to the conductive pads 114 through solder material, wherein the first passive components 130 are disposed on the surface of the package substrate 110 between the printed circuit board 160 and the package substrate 110. When the conventional electric package 100 is in a reflow process, further possibly owing to that the solder on the electrodes 130a is melted so that the first passive components 130 can not be positioned on the surface of the package substrate 110. Therefore, the first passive components 130 may drop on the printed circuit board 160. Accordingly, the manufacturing yield of assembling the conventional electric package 100 to the printed circuit board 160 will be affected and decreased.

### SUMMARY OF THE INVENTION

An object of the present invention is to provide an interconnection structure through passive component, which saves the space occupied by passive components in an electric package or on a printed circuit board.

According to the above mentioned object or other objects, the present invention provides an interconnection structure through passive component comprising a first substrate, a second substrate, a plurality of conductive blocks, and at least a passive component. Wherein, the second substrate is disposed on the first substrate. Further, the conductive blocks and the passive components are disposed between the first substrate and the second substrate. Wherein, the first substrate is structurally and electrically connected to the second substrate through the conductive blocks and the passive components.

As mentioned, the present invention disposes the passive components between two substrates, structurally separates the two substrates and electrically connects the two substrates. Accordingly, the interconnection structure through passive component of the present invention can save the space occupied by the passive components in an electric package or on a printed circuit board.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1 is a drawing schematically showing a cross-sectional view of a conventional interconnection structure through passive component.

FIG. 2A and FIG. 2B are drawings schematically showing cross-sectional views of an interconnection structure through passive component according to the first embodiment of the present invention.

FIG. 3 is a drawing schematically showing a cross-sectional view of an interconnection structure through passive component according to the second embodiment of the present invention.

FIG. 4 is a drawing schematically showing a cross-sectional view of an interconnection structure through passive component according to the third embodiment of the present invention.

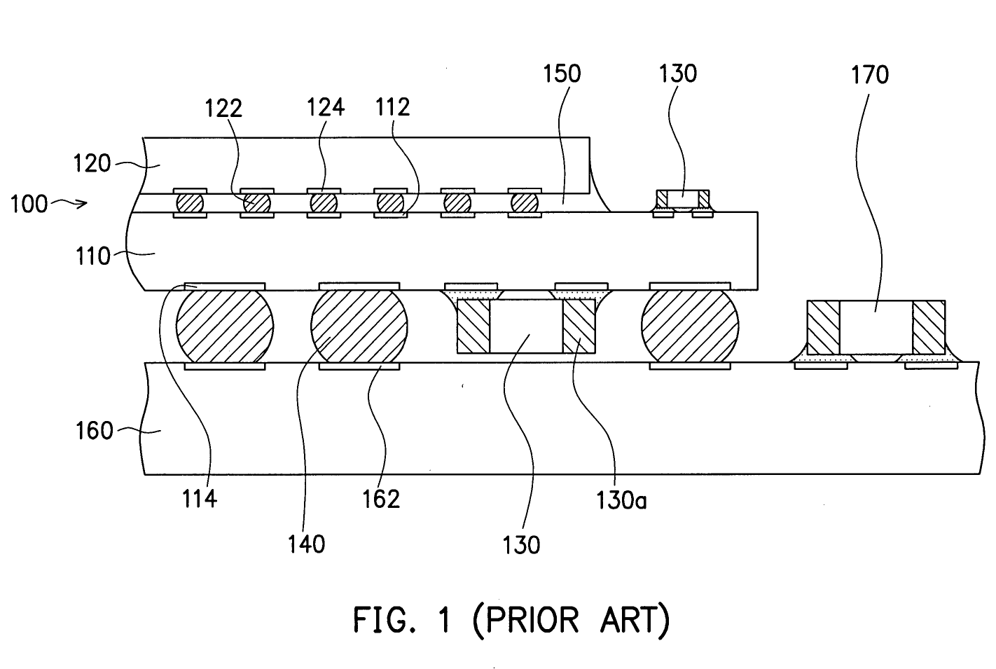

### DESCRIPTION OF THE PREFERRED EMBODIMENTS

### First Embodiment

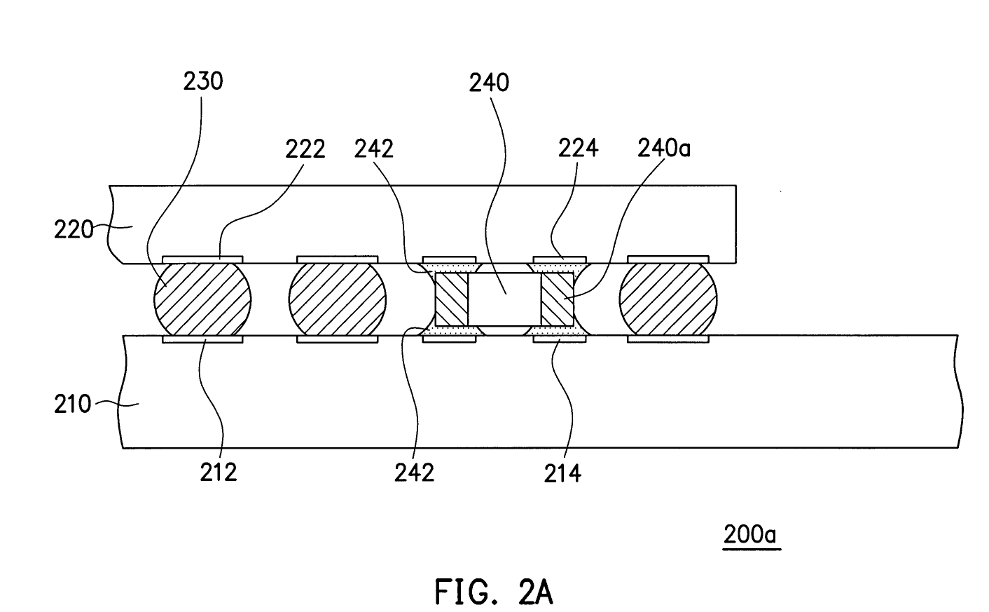

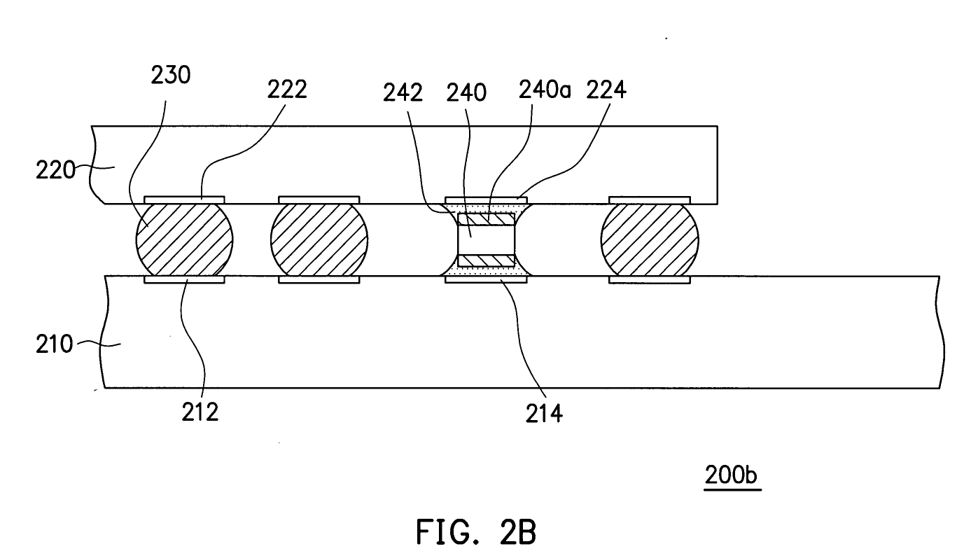

FIG. 2A and FIG. 2B are drawings schematically showing cross-sectional views of an interconnection structure through passive component according to the first embodiment of the present invention. First, as shown in FIG. 2A, the interconnection structure through passive component 200a comprises a first substrate 210, a second substrate 220, a plurality of conductive blocks 230, and at least a first passive component 240. Wherein, the second substrate 220 is disposed on the first substrate 210. Further, the conductive blocks 230 are disposed between the first substrate 210 and the second substrate 220. The first substrate 210 is electrically connected to the second substrate 220 through the conductive blocks 230. Furthermore, the first passive component 240 is disposed between the first substrate 210 and the second substrate 220 and structurally separates the first substrate 210 with the second substrate 220. The first passive component 240 is structurally and electrically connected to the first substrate 210 and the second substrate 220.

In detail, for example, the first substrate 210 is electrically connected to the second substrate 220 sequentially through the conductive pads 212, the conductive blocks 230 and the conductive pads 222. Further, the first substrate 210 can be electrically connected to the second substrate 220 sequentially through the conductive pads 214, the conductive material 242, the electrodes 240a of the first passive components 240, the conductive material 242 and the conductive pads 224. The conductive material 242 may be solder layer or conductive paste. Furthermore, the first passive component 240 may be a capacitor, a inductor, a resistor or an integrated passive component. Herein, only the situation of a capacitor as the first passive component 240 is used in the first embodiment of the present invention. When the first passive component 240 is the capacitor, the conductive pads 212 and 222 may be used as power source or connected to a ground. In addition, though the electrodes 240a of the first passive components 240 are directly and electrically connected to the conductive pads 212 and 222, the present invention does not limit the disposing types of the electrodes 240a of the first passive components 240. As shown in FIG. 2B, in the interconnection structure through passive component 200b, the electrodes 240a of the first passive components 240, for example, may be disposed separately to two opposite surfaces thereof, and the electrodes 240a are electrically connected to the conductive pads 214 or 224.

When the interconnection structure through passive component 200a or 200b are used in a flip chip package (FC package), the first substrate 210 can be a package substrate, and the second substrate 220 can be a chip. And the conductive blocks 230 can be bumps for flip chip. Further, when the interconnection structure through passive component 200a or 200b are used in a structure of a direct chip attachment (DCA) type or in a chip scale package (CSP), the first substrate 210 may be a printed circuit board, the second substrate 220 may be a chip, and the conductive blocks 230 may be the bumps for flip chip.

Owing to that the first passive component 240 is disposed between the first substrate 210 and the second substrate 220 for controlling the distance between the first substrate 210 and the second substrate 220, when the material of the conductive blocks 230 are solder, the conductive blocks 230 disposed between the first substrate 210 and the second substrate 220 will not easily collapse while reflowing. In addition, when the first substrate 210 is the package substrate and the second substrate 220 is the chip, owing to that the first passive component 240 is disposed between the first substrate 210 and the second substrate 220 without necessary to be disposed on the surface of the first substrate 210 which surface is positioned at the outer circumference of the second substrate 220, so that the interconnection structure through passive component 200a and 200b possess a smaller package area. Furthermore, when the first substrate 210 is the package substrate, the second substrate 220 is the chip and the first passive component 240 is the capacitor, owing to that the first passive component 240 is directly disposed under the first substrate 220 (i.e. chip) so that the first passive component 240 is closer to the second substrate 220 (i.e. chip), therefore the interconnection structure through passive component 200a and 200b possess a smaller electric voltage fluctuation.

### Second Embodiment

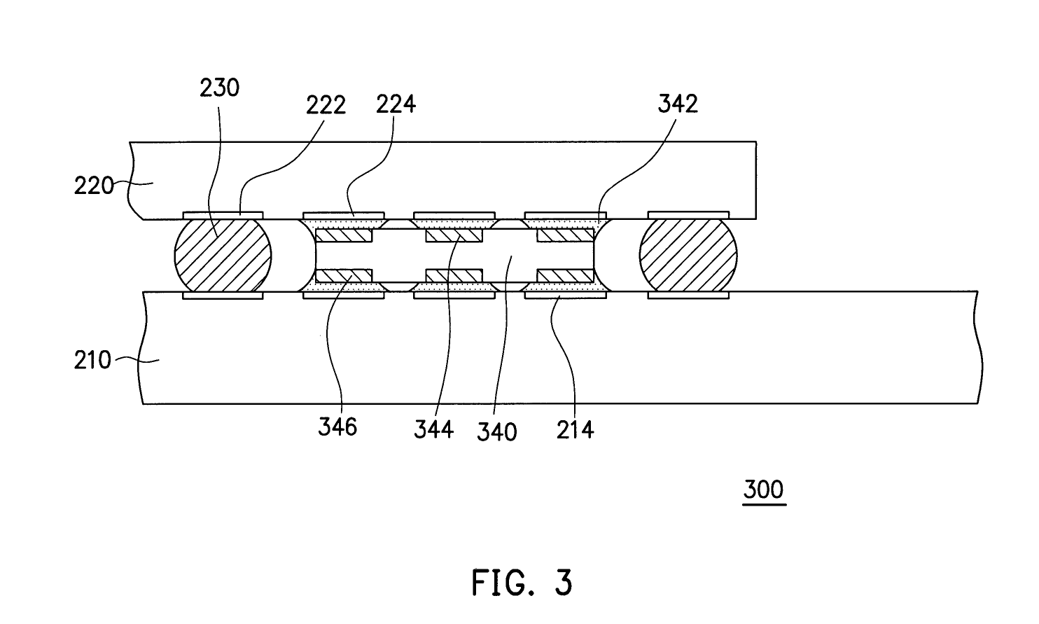

FIG. 3 is a drawing schematically showing a cross-sectional view of an interconnection structure through passive component according to the second embodiment of the present invention. As shown in FIG. 3, the second embodiment is similar to the first embodiment. The difference is that the first passive component in the second embodiment can be a passive component 340 with a plurality of electrodes. The passive component 340 has electrodes 344 and 346 separately disposed on two opposite surfaces thereof. Therefore, the first substrate 210 is structurally and electrically connected to the second substrate 220 sequentially through at least a conductive pad 212, a conductive material 342, the passive component 340 with the multiple electrodes, the conductive material 342, and at least a conductive pad 222. Note that the passive component 340 with the multiple electrodes can be designed as a panel-shape and the electrodes can be arranged in array, for example.

Similar to the first embodiment, in the second embodiment, the first substrate 210 can be the printed circuit board, the second substrate 220 can be the package substrate, and the conductive blocks 230 can be solder balls. Further, the first substrate 210 can be a printed circuit board, the second substrate 220 can be a chip, and the conductive blocks 230 can be bumps. Note that owing to the central region of the chip generally is power/ground region, as for the second substrate 220 as a chip, the panel-shape passive component 340 can be disposed at the central region of the chip.

### Third Embodiment

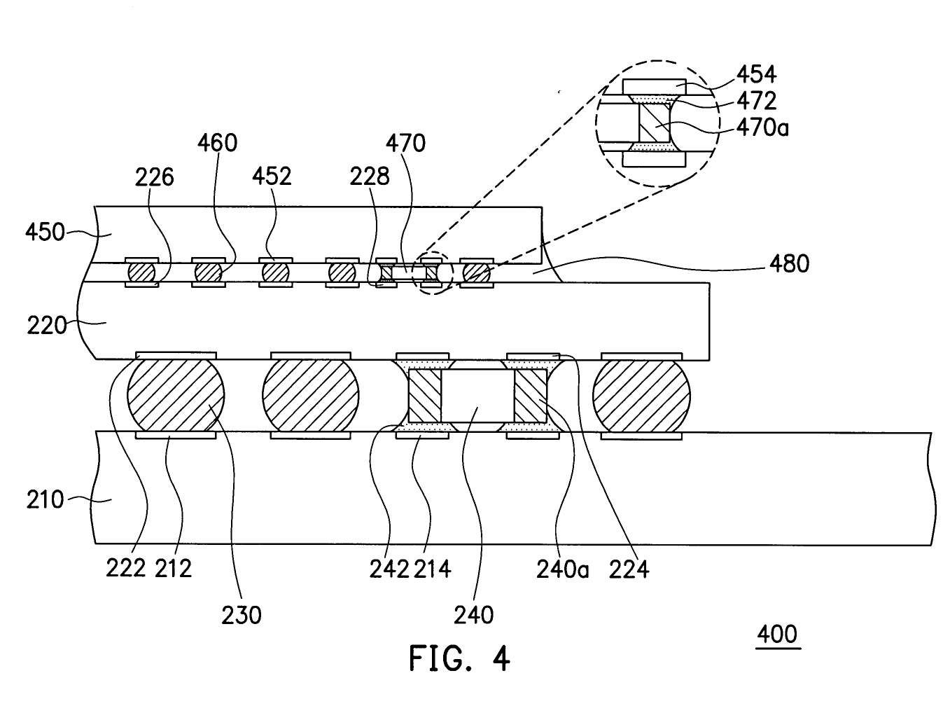

FIG. 4 is a drawing schematically showing a cross-sectional view of an interconnection structure through passive component according to the third embodiment of the present invention. As shown in FIG. 4, the third embodiment is similar to the first embodiment. The difference is that the interconnection structure through passive component 400 in the third embodiment further comprises a chip 450, a plurality of bumps 460, at least a second passive component 470 and an underfill 480. Wherein, the chip 450 is disposed on the second substrate 220. Further, the bumps 460 are disposed between the second substrate 220 and the chip 450, and the chip 450 is structurally and electrically connected to the second substrate 220 through the bumps 460. As for more details, the chip 450 is electrically connected to the second substrate 220 sequentially through the conductive pads 452, the bumps 460 and the conductive pads 226.

In addition to the above mentioned, the second passive component 470 is disposed between the second substrate 220 and the chip 450 and structurally separates the second substrate 220 and the chip 450. Two electrodes 470a of the second passive component 470 are electrically connected to the second substrate 220 and the chip 450. In detail, the chip 450 is electrically connected to the second substrate 220 sequentially through the conductive pads 454, the conductive material 472, the second passive component 470, the conductive material 472 and the conductive pads 228. Further, the underfill 480 is disposed between the chip 450 and the second substrate 220 for covering the bumps 460.

Note particularly that the panel-shape passive component 340 of the second embodiment can also be disposed between the chip 450 and the second substrate 220. Further, the second substrate 220 and the chip 450 constitute, for example, an electric package. However, the electric package can also be concluded by the second substrate 220 only. In addition, the electric package is not limited to the chip 450 being electrically connected to the second substrate 220 through the bumps 460. In other embodiments, the chip 450 can be electrically connected to the second substrate 220 by a plurality of bonding wires.

In summary, the interconnection structure through passive component of the present invention has the following advantages:

1. The passive component of the present invention is disposed between the first substrate and the second substrate for controlling the distance between the first substrate and the second substrate. When the material of the conductive blocks is solder, the conductive blocks (solder balls or bumps) disposed between the first substrate and the second substrate will not collapse easily while reflowing.

2. The present invention disposes the passive component between the first substrate (for example the printed circuit board or package substrate) and the second substrate (for example the chip), which were designed to be disposed on the surface of the first substrate. Since the passive component is allowed to be disposed between the first substrate and the second substrate, the interconnection structure through passive component of the present invention possess a smaller package area.

3. Comparing with the conventional technology, when the passive component is the capacitor, because the passive component is disposed between the first substrate (for example the printed circuit board or package substrate) and the second substrate (i.e. the chip), the passive component is closer to the second substrate (i.e. chip). Accordingly, the interconnection structure through passive component of the present invention possesses a smaller electric voltage fluctuation.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. An interconnection structure through passive component, comprising:
a first substrate;
a second substrate disposed on the first substrate;
a plurality of conductive blocks disposed between the first substrate and the second substrate, wherein the first substrate is structurally and electrically connected to the second substrate by the conductive blocks; and
at least a first passive component disposed between the first substrate and the second substrate, wherein the first substrate is structurally and electrically connected to the second substrate by the first passive component.

2. The interconnection structure through passive component of claim 1, wherein at least an electrode of the first passive component is electrically connected to the first substrate and the second substrate.

3. The interconnection structure through passive component of claim 1, wherein at least an electrode of the first passive component is electrically connected to the first substrate, and at least another electrode of the first passive component is electrically connected to the second substrate.

4. The interconnection structure through passive component of claim 1, wherein the first passive component is a panel-shape passive component.

5. The interconnection structure through passive component of claim 4, wherein the panel shape passive component has a plurality of electrodes separately disposed on two opposite surfaces thereof.

6. The interconnection structure through passive component of claim 1, wherein the first substrate is a package substrate, the second substrate is a chip, and the conductive blocks are bumps.

7. The interconnection structure through passive component of claim 1, wherein the first substrate is a printed circuit board, the second substrate is a chip, and the conductive blocks are bumps.

8. The interconnection structure through passive component of claim 1, wherein the first substrate is a printed circuit board, the second substrate is a package substrate, and the conductive blocks are conductive balls.

9. The interconnection structure through passive component of claim 8, further comprising a chip disposed on the second substrate and electrically connected to the second substrate.

10. The interconnection structure through passive component of claim 9, further comprising a plurality of bumps disposed between the second substrate and the chip, wherein the chip is electrically connected to the second substrate by the bumps.

11. The interconnection structure through passive component of claim 10, further comprising at least a second passive component disposed between the second substrate and the chip, wherein the chip is electrically connected to the second substrate by the second passive component.

12. The interconnection structure through passive component of claim 11, wherein at least an electrode of the second passive component is electrically connected to the second substrate and the chip.

13. The interconnection structure through passive component of claim 11, wherein at least an electrode of the second passive component is electrically connected to the second substrate, and at least another electrode of the second passive component is electrically connected to the chip.

14. An interconnection structure through passive component, comprising:
a printed circuit board;
an electric package disposed on the printed circuit board;
a plurality of conductive blocks disposed between the printed circuit board and the electric package, wherein the printed circuit board is structurally and electrically connected to the electric package by the conductive blocks; and
at least a first passive component disposed between the printed circuit board and the electric package, wherein the printed circuit board is structurally and electrically connected to the electric package by the first passive component.

15. The interconnection structure through passive component of claim 14, wherein at least an electrode of the first passive component is electrically connected to printed circuit board and the electric package.

16. The interconnection structure through passive component of claim 14, wherein at least an electrode of the first passive component is electrically connected to the printed circuit board, and at least another electrode of the first passive component is electrically connected to the electric package.

17. The interconnection structure through passive component of claim 14, wherein the first passive component is a panel-shape passive component.

18. An interconnection structure through passive component, comprising:
a first substrate;
a second substrate disposed on the first substrate; and
at least a passive component disposed between the first substrate and the second substrate, wherein the first substrate is structurally and electrically connected to the second substrate by the first passive component.

19. The interconnection structure through passive component of claim 18, wherein at least an electrode of the first passive component is electrically connected to the first substrate and the second substrate.

20. The interconnection structure through passive component of claim 18, wherein at least an electrode of the first passive component is electrically connected to the first substrate, and at least another electrode of the first passive component is electrically connected to the second substrate.

21. The interconnection structure through passive component of claim 18, wherein the first substrate is a package substrate, and the second substrate is a chip.

22. The interconnection structure through passive component of claim 18, wherein the first substrate is a printed circuit board, and the second substrate is a chip.

23. The interconnection structure through passive component of claim 18, wherein the first substrate is a printed circuit board, and the second substrate is a package substrate.
